(19) United States
(12) Patent Application Publication
(10) Pub. No.: US 2021/0075362 A1
(43) Pub. Date: Mar. 11, 2021

(54) COVERING SLAB FOR FUNCTIONALISED INFRASTRUCTURE

(71) Applicants: COMMISSARIAT A L'ÉNERGIE ATOMIQUE ET AUX ENERGIES ALTERNATIVES, PARIS (FR); COLAS, Paris (FR)

(72) Inventors: Nicolas CHAINTREUIL, MONTMELIAN (FR); Franck BARRUEL, LE BOURGET DU LAC (FR); Eric COQUELLE, VERSAILLES (FR)

(21) Appl. No.: 16/772,211

(22) PCT Filed: Dec. 4, 2018
(86) PCT No.: PCT/FR2018/053099

§ 371 Date: Jun. 12, 2020

(30) Foreign Application Priority Data
Dec. 13, 2017 (FR) 1762046

(51) Int. Cl. H02S 20/21; H02S 40/32; H02J 50/10; H02J 3/38; H02J 50/40

(52) U.S. Cl. CPC H02S 20/21; H02S 40/32; H02J 2300/24; H02J 3/381; H02J 50/402; H02J 50/10

(57) ABSTRACT

Disclosed is a covering slab for infrastructure such as a roadway in the form of a road or a motorway, a wall or a roof, the infrastructure being functionalized by the addition of a function such as an electrical energy generator and/or an electrical energy receiver, the slab being formed by a monobloc assembly including: an assembly for the electrical functionalization of the slab, including a first layer, called an outer layer; an electronics block connected to the electrical functionalization assembly and including at least one bidirectional static converter; and a contactless energy transmission block including an inductive coupler provided with two terminals connected to the bidirectional static converter of the electronics block and having a coupling surface located opposite the outer layer.

### TECHNICAL FIELD OF THE INVENTION

The present invention relates to a covering slab for a functionalized infrastructure. The invention further relates to a contactless energy transmission system using said covering slab as well as to a functionalized infrastructure using said system.

The term “infrastructure” means, in a not limiting manner, a roadway in the form of a road or motorway as well as a wall or a roof.

The term “functionalized” means, in a not limiting manner, the addition of a function such as an electrical energy generator and/or such as an electrical energy receiver.

Thus, the issue is to add, by means of the infrastructure, one or more functions such as generation of electrical energy by using photovoltaic cells, visual or sound signaling, lighting, and also counting vehicles or charging batteries of an electrical vehicle.

### STATE OF THE ART

In order to make the space profitable, especially in the agglomerations, it has been proposed to make roads which comprise photovoltaic cells. Since the roads are often well exposed to sunlight, they are able to easily collect luminous energy. By integrating therein photovoltaic cells, they can convert collected luminous energy into electrical energy. The electrical energy produced by the roads can then be used in different ways. Converters are, for example, judiciously positioned at the side of roads in order to reflect generated electrical energy to the network or to any other installations.

Referenced documents FR3016257A1 and U.S. Pat. No. 8,080,901B2 describe such solutions of roads functionalized by means of photovoltaic cells or energy converters of the piezoelectrical or thermoelectrical type.

Documents WO2016/16165A1 and WO2016/16170A1 describe, as far as they are concerned, a multilayer structure of a photovoltaic module which can be used for making the surface course of a functionalized roadway. That multilayer structure has especially mechanical characteristics which are sufficient for absorbing shocks and for being exposed to different mechanical strains of a surface course of a roadway.

However, even if the project of functionalizing the roads is particularly interesting, at the moment that project encounters a number of practical problems. The electrical connectors often tend to wear by oxidation. Further, once the infrastructure is installed, their maintenance and cleaning are complicated, and the least malfunction often needs the road to be broken in order to access to the defective parts.

Thus, at the time being, there is no solution that would allow to build a functionalized infrastructure which is reliable, low-cost, easy to install and to maintain.

Further, the existing solutions often are barely adapted to comply with security regulations concerning persons. Indeed, in view of the important mechanical strain that the roads are exposed to, it is essential to assure a voltage level of the TBTS type (Very Low Security Voltage) over the first centimeters of thickness of the roadway (about 5 centimeters) in order to avoid any risk of electric shock in case of deterioration of the roadway. A voltage level of the TBTS type means a voltage of less than 60V. Ideally, the higher voltage (Low Voltage) may only be accessible at a higher depth.

It is an object of the invention, to propose a solution for installing a functionalized infrastructure in a simple way, at low costs, which is easy to install and to maintain in case of malfunction, and which allows for taking into account the limitations mentioned further up in terms of security voltage level.

### DESCRIPTION OF THE INVENTION

The object is attained by a covering slab for an infrastructure such as a roadway in the form of a road or motorway as well as a wall or a roof, said infrastructure being functionalized by the addition of a function such as an electrical energy generator and/or such as an electrical energy receiver, said slab being formed by a monobloc assembly comprising:
an assembly for the electrical functionalization of said slab, comprising a first layer, called an outer layer;
an electronics block connected to said electrical functionalization assembly and comprising at least one bidirectional static converter;
a contactless energy transmission block comprising an inductive coupler provided with two terminals connected to the bidirectional static converter of said electronics block and having a coupling surface located opposite said outer layer.

According to a particular embodiment, the electrical functionalization assembly comprises a block for generating electrical energy.

According to a particular aspect, the electrical energy generator block may comprise photovoltaic cells intended to convert luminous energy into an electrical energy.

According to another particular embodiment, the electrical functionalization assembly comprises a block for receiving electrical energy.

According to a particular aspect, the electrical energy receiving block may comprise an electronics circuit for luminous and/or sound signaling.

According to a further particular aspect, the electrical energy receiving block may comprise a device for charging an electrical appliance by induction.

According to a further particular aspect, the electrical energy receiving block may comprise a device for counting vehicles.

According to a further particular aspect, the electrical energy receiving block may comprise one or more terminals for connection to one or more wireless communication networks.

According to a further particular aspect, the electrical energy receiving block may comprise a heating structure.

The invention further relates to a system for contactless transmission of electrical energy for an infrastructure such as a roadway in the form of a road or motorway as well as a wall or a roof, said infrastructure being functionalized by the addition of a function such as an electrical energy generator and/or such as an electrical energy receiver, said system comprising:
a first part comprising n blocks for contactless transmission of energy, each one comprising an inductive coupler, with n being more than or equal to 1, each inductive coupler having a coupling surface;
a second part comprising n covering slab(s), each covering slab being as defined above.

According to a particular embodiment:
the first part comprises n blocks for contactless transmission of energy, n being more than or equal to 2;
each inductive coupler of the first part is electrically connected to an adjacent inductive coupler by means of a connection cable.

According to another particular embodiment, the first part comprises n static converter(s), each one being associated to a separate inductive coupler of the first part.

According to a particular embodiment, in the first part, the n static converter(s) are of the AC/DC type, and the system comprises a central converter of the DC/AC type, and the n static converter(s) of the AC/DC type are connected in parallel to the central converter.

According to a particular aspect, the system can comprise a module for stocking electrical energy which is connected in parallel to the n converter(s) connected to the central converter.

According to another particular embodiment, in the first part, the n static converter(s) are of the AC/AC type.

According to another particular embodiment, the system comprises a central converter of the AC/AC type, and the n inductive coupler(s) of the first part are connected in parallel to the central AC/AC converter.

According to another particular embodiment, in the first part, the n static converter(s) are of the DC/AC type and the system comprises a central converter of the AC/AC type, and the n static converter(s) of the DC/AC type are connected in parallel to the central converter.

The invention is also related to a functionalized infrastructure comprising a system for contactless transmission of electrical energy, said infrastructure comprising a lower layer which comprises a surface to be covered and in which n cavities are formed, n being more than or equal to 1, said infrastructure comprising:
a first part comprising an inductive coupler located in each cavity such as to have a first coupling surface;
a second part comprising n covering slab(s) such as defined above, each covering slab being positioned on said surface to be covered such as to cover a separate cavity and to turn its outer face to the outside of said cavity and its coupling surface to the inside of said cavity facing the coupling surface of the inductive coupler located inside the cavity.

According to a particular aspect:
said surface to be covered of the lower layer comprises n cavities, n being more than or equal to 2;
said infrastructure comprises a trench linking each cavity to an adjacent cavity;
the first part of the system comprises several inductive couplers, each being located in a separate cavity;
from one cavity to an adjacent cavity, the inductive couplers are linked to one another by a connection cable extending in said trench.

According to another particular aspect, said n covering slabs are juxtaposed in such a way that their outer surface of their outer layer is located in a same plane.

The invention is further related to a method of installing a functionalized infrastructure as defined above, the method comprising steps of:
forming n cavities in the lower layer, n being more than or equal to 2;
positioning the first part such as to occupy each cavity with a separate inductive coupler;
positioning a separate covering slab on each cavity such as to turn its outer face to the outside of the cavity and its coupling surface to the inside of said cavity opposite the coupling surface of the inductive coupler located inside the cavity.

### BRIEF DESCRIPTION OF THE DRAWINGS

Other characteristic features and advantages will be apparent in the following detailed description, in conjunction with the accompanying drawings in which:

FIGS. 1A and 1B show, in a schematic manner, respectively as a perspective view and as a cross-section view, a covering slab according to the invention;

FIG. 2 shows, as a cross-section view, the different layers of an electrical functionalization assembly of the slab of the photovoltaic module type;

FIGS. 3A and 3B show, respectively as a perspective view and as a cross-section view, a block for contactless transmission of energy used in the system for contactless transmission of energy of the invention;

FIGS. 4A through 4D show the main steps of embodying a functionalized infrastructure according to the invention;

FIGS. 5A and 5B show the principle of the installation of the first part of the system according to the invention;

FIGS. 6A and 6B show, seen from above and seen as a cross-section view, a functionalized infrastructure of the roadway type provided with several adjacent slabs;

FIGS. 7 through 10 show several possible electrical architectures of the system for contactless transmission of energy of the invention.

### DETAILED DESCRIPTION OF AT LEAST ONE EMBODIMENT

In the following description, the terms “upper”, “lower”, “high”, “low” or other terms have to be considered with respect to an axis (A) which will be defined as being perpendicular to the plane formed by a slab (vertical axis in the plane of the page in the enclosed figures).

As described above, “infrastructure” means for example an area for circulation.

“Area for circulation” means, in a not limiting manner, any area foreseen for circulation of pedestrians and/or vehicles, such as, for example, a roadway in the form of a road or motorway, a bicycle path, a sidewalk, or a parking lot.

It will be considered that the infrastructure 1 to be functionalized comprises a lower layer 10 provided with a surface 100 to be covered with a functional layer which allows said infrastructure 1 to be functionalized.

The invention aims especially at producing said functional layer by using covering slabs located in an adapted manner, for example in an adjacent and contiguous manner, in order to cover at least partially the surface 100 of the lower layer 10 of said infrastructure 1. All slabs have, for example, an identical shape, for example rectangular or square.

In case of an infrastructure of the area for circulation type, the lower layer is composed, for example, of an asphalt. Of course, since said lower layer is not part of the invention, any other monolayer or multilayer structure can be foreseen.

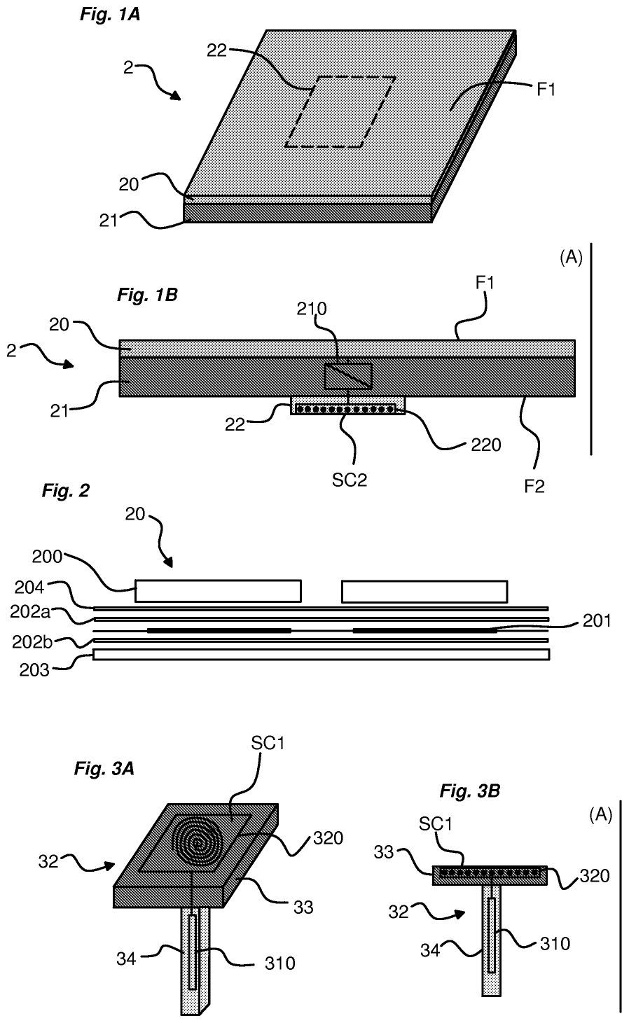

Referring to FIGS. 1A and 1B, a covering slab 2 according to the invention has the characteristic features described below.

The slab 2 of the invention has the form of a monobloc element, which means that it is a single piece. Advantageously, it has a first face, called upper face F1, intended for forming the external face of the infrastructure, and a lower face F2 opposite and preferably in parallel to the upper face. Between its two faces, the slab comprises several functional assemblies or blocks. Those functional assemblies and blocks preferably are located in one or several hermetic housings fixed between them and having, if necessary, electrical connection means. Its upper face F1 advantageously is plane. Said external layer, which defines the outline of the slab, can have any possible shape.

Thus, the covering slab 2 comprises an electrical functionalization assembly 20 which allows to provide the slab exclusively with an electrical function of the type of generating electrical energy or an electrical function of the type of receiving electrical energy (i.e. a consumer). The infrastructure that comprises several slabs of that type can be provided with one or several functions, according to the type of slabs used.

In a not limiting manner, that electrical functionalization assembly 20 of the slab comprises a first layer 200 having an upper face, also called an external face, forming the upper face F1 of the slab 2 mentioned above and intended to form the surface course of the area for circulation.

The covering slab 2 comprises an electronics block 21 linked to the electrical functionalization assembly 20 and comprising at least one converter 210.

In that same monobloc element, the covering slab 2 also comprises a block 22 for contactless transmission of energy provided with at least one inductive coupler. That block will be fixed, for example, on the above defined lower face F2 by any possible fixing means, and electrically connected to the different circuits above it.

According to the invention, the electrical functionalization assembly 20 can have different configurations depending on the type of functionality, generator type or receiver type, to be added to the slab and the infrastructure 1. It has to be noted that the electronics block 21 and the block 22 for contactless transmission of energy of the slab, which will be described in details hereafter, preferably always are identical, whatsoever the configuration of the electrical functionalization assembly 20 might be.

In a first configuration, providing the slab exclusively with a type of generating electrical energy, the electrical functionalization assembly 20 is shaped as a photovoltaic module. Preferably, it comprises the structure described in the patent applications WO2016/16165A1 and WO2016/16170A1 and shown in FIG. 2. Without going into too much detail, in that structure of a photovoltaic module, the first layer 200 described above is transparent over the whole thickness in order to let a luminous flux pass through.

The term “transparent” means that the material forming the first layer is at least partially transparent to visible light.

The first layer 200 will be made, for example, as a single plate or as several juxtaposed plates. It will be made, for example, of a transparent polymer material such as, for example, polymethylmethacrylate (PMMA).

Further, the photovoltaic module comprises a plurality of photovoltaic cells 201 connected with one another in series or in series/parallel. In a known manner, they are intended for capturing the light flux that passes through the first layer.

The photovoltaic module comprises an encapsulating assembly in which the photovoltaic cells are encapsulated. That encapsulating assembly is preferably formed by two layers 202a, 202b of an encapsulating material between which the photovoltaic cells are encapsulated. For melting both encapsulating layers 202a, 202b in order to get a single layer in which the photovoltaic cells 201 are encapsulated, a rolling operation is performed. The method of production is described in detail in both patent applications mentioned above, which are incorporated here by reference. Since that method is not part of the invention, it is not described precisely in the present application.

The term “encapsulating” or “encapsulated” used here means that the photovoltaic cells 201 are located in a preferably hermetic volume formed by assembling both layers of the assembly.

The photovoltaic module comprises a second layer 203 forming the rear face of the module. The encapsulating assembly is positioned between the first layer 200 and that second layer 203. That second layer 203 will be made, for example, from a composite type material, for example of the polymer/glass fiber type.

Advantageously, the photovoltaic module comprises an intermediate layer 204, called “damping”, which is located between the first layer 200 and the upper layer 202a of the encapsulating assembly (202a, 202b) and which allows assembling, especially by gluing, the first layer 200 onto the encapsulating assembly.

Advantageously, the photovoltaic module comprises an adhesive layer (not shown) located between the encapsulating assembly and the second layer 203. That layer serves for assembling, especially by gluing, the second layer 203 to the encapsulating assembly.

According to other configurations defined below, the electrical functionalization assembly can comprise, in an exclusive manner, a circuit for receiving electrical energy.

Thus, in a second configuration, the electrical functionalization assembly 20 can comprise an electronics circuit for luminous and/or sound signaling.

The electronics circuit for luminous signaling comprises, for example, one or several light emitting diodes allowing to provide lighting.

In that second configuration, the structure of the electrical functionalization assembly 20 is similar to that of the first configuration of the photovoltaic type. The differences are constituted by the fact that it uses a signaling block with light emitting diodes.

In a third configuration, the electrical functionalization assembly can comprise a module for charging an electrical vehicle by induction. That solution allows to charge an electrical vehicle when it is stationary on the road or on a place of a parking lot.

In a fourth configuration, the electrical functionalization assembly can comprise one or several electrical sockets in order to connect to it all types of electrical appliances.

In a fifth configuration, the electrical functionalization assembly can comprise all types of sensors, for example of the temperature sensor type or of the vehicle counting type.

In a sixth configuration, the electrical functionalization assembly can comprise one or several terminals for connecting to one or several networks of wireless communication. That may be, for example, a terminal operating according to a known communication protocol such as WIFI, Bluetooth, 3G or 4G, or an equivalent protocol. It is then about proposing a slab provided with one or several of these communication functions.

In a seventh configuration, the electrical functionalization assembly can comprise a heating structure comprising, for example, resistors or a mesh allowing for heating the infrastructure, especially for de-icing in winter.

In order to respond to all functions of the generator type or the receiver type, the covering slab 2 of the invention further comprises an electronics block 21 comprising at least one static voltage converter 210 that is bidirectional for current flow. By means of that converter, according to its function, the slab 2 can act as a current generator or as a current receiver.

For an electrical functionalization assembly 20 with photovoltaic cells, the voltage converter will here be of the DC/AC type for converting continuous current provided by the photovoltaic cells into alternating current.

For an electrical functionalization assembly 20 of the receiver type, the converter has a topology according to the used receiver type. If the receiver is, for example, an electronic circuit for signaling, the voltage converter will be of the AC/DC type, wherein the electronic circuit for signaling is connected to the DC side.

For an electrical functionalization assembly 20 provided with a module for electrical charging an electrical vehicle by induction, the converter will be of the AC/AC type.

For an electrical functionalization assembly 20 with a heating structure, the voltage converter will be of the AC/AC type.

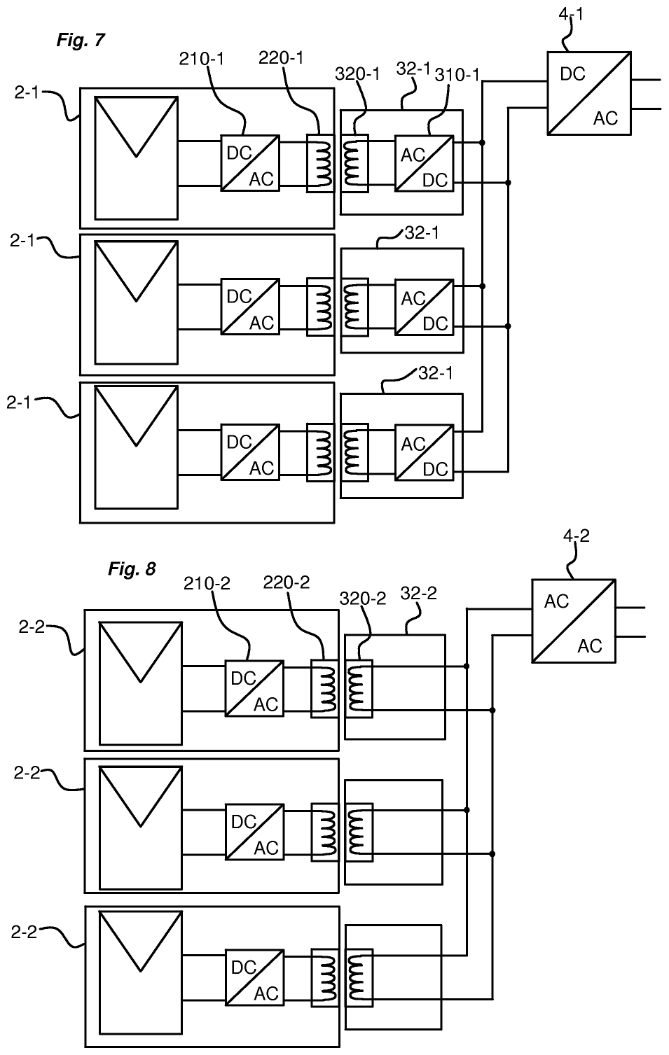

With reference to FIGS. 7 through 10, the different possible electrical configurations on different functionalized infrastructures will be described in detail.

The slab 2 finally comprises a block 22 for contactless transmission of energy comprising an inductive coupler 220. In a known manner, that inductive coupler 220 comprises a winding of turns and is intended for being positioned opposite a second inductive coupler for performing a contactless, i.e. a wireless, transfer of electrical energy by electromagnetic coupling. One of these two couplers thus is the primary winding of a transformer and the other one of these two couplers is the secondary winding of the transformer. According to the nature of the electrical functionalization assembly of the slab, the transfer of energy between these two couplers will be done in one direction or the other. If the electrical functionalization assembly comprises a current generator (for example a photovoltaic module), the transfer of energy will be done from the inductive coupler of the slab to the second coupler. However, if the electrical functionalization assembly comprises one or several receivers (for example light emitting diodes), the transfer of energy will be done in the other direction, i.e. from the second coupler to the coupler of the slab.

The arrangement of the inductive coupler 220 in block 22 for contactless transmission of energy defines a coupling surface SC2 located opposite the upper face F1 of the slab and advantageously in parallel to the lower face F2 of the slab.

The inductive coupler 220 comprises two terminals which are connected to the voltage converter 210 of block 21 mentioned above.

The block 22 for contactless transmission of energy can be produced as a separate element that is fixed on the slab 2 or is integrated into the electronics block described above. The block 22 can especially comprise a separate housing enclosing the inductive coupler 220 or be located in the same housing as the electronics block 21.

The winding forming the inductive coupler 220 can be made in different configurations. It can be, for example, a coil of the planar type wherein the plane defined by the coil defines the above-mentioned coupling surface. The winding of the planar coil is produced, for example, by screen-printing on a printed circuit. One of the faces of the printed circuit then forms the coupling surface defined above.

The invention also relates to the system of contactless (i.e. wireless) transmission of energy, in which one or several covering slabs 2 of the above described type are included.

Thus, this system is composed of two parts, a first part 3 and a second part, between which the contactless transmission of energy is operated.

The second part of the system is formed by n covering slabs 2 as described above, n being more than or equal to 1. If the number n of slabs is more than or equal to two, all covering slabs 2 used in that second part of the system could have identical functions, thus proposing a single functionality to the system (for example only slabs of the photovoltaic type), or different functions in order to propose different functionalities to the system (for example a mixture of slabs of the photovoltaic type with slabs having a functionalization assembly of the receiver type (e.g. light emitting diodes)).

With reference to FIGS. 3A and 3B, the first part 3 of the system comprises, as such, n blocks 32 for contactless transmission of energy, n being more than or equal to 1. Each block 32 comprises an inductive coupler 320. Each inductive coupler 320 of that first part is intended to be associated to a separate inductive coupler 220 of the second part. The inductive coupler 320 used in the first part has a mechanical design which is identical to the one of the inductive coupler of the slab to which it is associated. Thus, it has a coupling surface SC1 intended to be positioned parallel to the coupling surface SC2 of the slab in order to assure a contactless transfer of energy. The characteristic features of positioning between two windings, in order to get the best possible contactless transfer of energy, are well known in the state of the art and, therefore, are not described in the present application. However, it can be noted that the chosen solution of positioning will be an optimum along the x-axis and the y-axis and perhaps variable in the third dimension (along the height defined by the z-axis). The documents which relate especially to solutions for charging by induction, describe such characteristic features.

For lodging each block 32 for contactless transmission of energy, the first part 3 advantageously comprises one or several housings. In the following description, it is considered that each block for contactless transmission of energy has a structure in which the inductive coupler 320 is lodged in a first housing 33 that has at least one wall defining a preferably plane external face, and an internal face opposite to which the coupling surface SC1 of the inductive coupler 320 of the block is positioned. This first housing will advantageously be hermetic and particularly resistant in order to be used in an infrastructure such as one of the cells described above.

According to the configuration of the system, the block 32 for contactless transmission of energy can comprise an adapted static converter 310 comprising two connection terminals between which the inductive coupler 320 is connected. That static converter 310 will be of the AC/DC or the AC/AC type, the inductive coupler being connected on the AC side. The block advantageously comprises a second housing 34 in which the static converter 310 is lodged. The second housing is fixed to the first housing. Both housings are, for example, fixed to one another. The second housing extends under the first housing opposite the coupling surface. Electrical connection means are foreseen in order to assure the electrical connection between the inductive coupler and the converter.

Of course, in the block 32 for contactless transmission of energy, any other configuration of the inductive coupler and the converter could be foreseen. The advantage of the aforementioned embodiment is based on a much easier thermal managing of the static converter in the asphalt, since it is farther away from external thermal conditions.

Each block 32 for contactless transmission of energy of the first part 3 is electrically connected or included in an electrical design. This electrical design can vary, especially according to the functions of the slabs 2 used.

With reference to FIG. 7, a first electrical design (identified by the index 1 in the reference numerals) of the system is as follows:
A first part 3 which comprises n blocks 32-1 for contactless transmission of energy, n being more than or equal to 1 (in FIG. 7: n=3). Each block for contactless transmission of energy takes along an inductive coupler 320-1 and a static converter 310-1 of the AC/DC type, the inductive coupler being connected to the AC side of the converter 310-1.
A second part comprising n covering slabs 2-1 with an electrical functionalization assembly of the photovoltaic module type. Each covering slab 2-1 takes along, in its electronics block, a converter 210-1 of the DC/AC type, the photovoltaic module being connected to the DC side of the converter and the inductive coupler 220-1 of the slab being connected to the AC side of the converter.
A central converter 4-1 of the DC/AC type and a DC bus having two lines to which the converters 310-1 of the AC/DC type of the first part 3-1 are connected in parallel.

That first design especially allows to work at relatively high frequencies (at least 100 kHz) at the couplers, allowing the highest coupling performance possible and, at the same time, maintaining a relatively compact coupling design (formed by the two opposite couplers). Indeed, the higher the transmission frequency is, the more compact the couplers can be for the same power, since their volume depends directly on the operating frequency.

With reference to FIG. 8, a second design (identified by the index 2 in the reference numerals) of the electrical system is as follows:
A first part 3-2 which comprises n blocks 32-2 for contactless transmission of energy, n being more than or equal to 1 (in FIG. 8: n=3). Each block for contactless transmission of energy takes along an inductive coupler.
A second part comprising n covering slabs 2-2 with an electrical functionalization assembly of the photovoltaic module type. Each covering slab takes along, in its electronics block, a converter 210-2 of the DC/AC type, the photovoltaic module being connected to the DC side of the converter and the inductive coupler 220-2 of the slab being connected to the AC side of the converter.
A central converter 4-2 of the AC/AC type and an AC bus having two lines to which the inductive couplers of the first part are connected in parallel.

That second design of the system does not use converters in its first part, but uses a central converter 4-2 of the AC/AC type to which the couplers of the first part are connected in parallel. That design has the advantage to reduce the number of power converters used. The frequency on the AC bus is several kHz. A compromise has to be found between the different parameters which are the frequency on the AC bus, the performance of each inductive coupler of the first part, and the line losses.

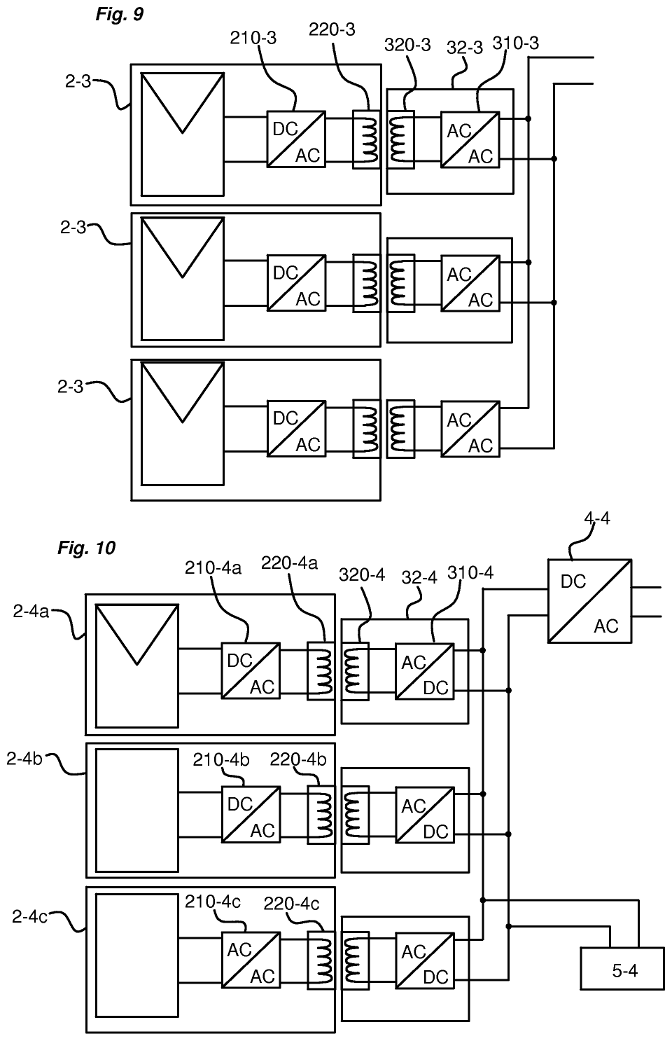

With reference to FIG. 9, a third electrical design (identified by the index 3 in the reference numerals) of the system is as follows:
A first part 3-3 which comprises n blocks 32-3 for contactless transmission of energy, n being more than or equal to 1 (in FIG. 9: n=3). Each block for contactless transmission of energy takes along an inductive coupler 320-3 and a voltage converter 310-3 of the AC/AC type, the inductive coupler being connected to the AC side of the converter.
A second part comprising n covering slabs 2-3 with an electrical functionalization assembly of the photovoltaic module type. Each covering slab takes along, in its electronics block, a converter 210-3 of the DC/AC type, the photovoltaic module being connected to the DC side of the converter and the inductive coupler 220-3 of the slab being connected to the AC side of the converter.

That third design eliminates the central converter of the preceding designs.

With reference to FIG. 10, a fourth electrical design (identified by the index 4 in the reference numerals) of the system is as follows:
A first part 3-4 which comprises n blocks 32-4 for contactless transmission of energy, n being more than or equal to 1 (in FIG. 10: n=3). Each block for contactless transmission of energy takes along an inductive coupler 320-4 and a converter 310-4 of the AC/DC type, the inductive coupler 320-4 being connected to the AC side of the converter.
A second part comprising n covering slabs 2-4, the covering slabs being provided with separate electrical functionalization assemblies. A first slab 2-4a comprises an electrical functionalization assembly of the photovoltaic module type. A second slab 2-4b comprises an electrical functionalization assembly of the receiver type with luminous signaling by diodes D. A third slab 2-4c comprises an electrical functionalization assembly of the receiver type with a module Mch for charging electrical vehicles by induction. The first slab 2-4a takes along, in its electronics block 21-4a, a converter 210-4a of the DC/AC type, the photovoltaic module being connected to the DC side of the converter and the inductive coupler of the slab being connected to the AC side of the converter 210. The second slab 2-4b takes along, in its electronics block, a converter 210-4b of the DC/AC type, the signaling block being connected to the DC side of the converter and the inductive coupler of the slab being connected to the AC side of the converter. The third slab 2-4c takes along, in its electronics block, a converter 210-4c of the AC/AC type, the module for charging by induction being connected to the AC side of the converter and the inductive coupler of the slab being connected to the AC side of the converter.
A central converter 4-4 of the DC/AC type and a DC bus having two lines which are connected in parallel to each inductive coupler of the AC/DC type of the first part.
A module 5-4 for stocking electric energy, connected to the DC bus.

That fourth design of the system allows to show how the structure of the system would be in a functionalized infrastructure provided with slabs having several separate functions (photovoltaic, signaling, charging by induction . . . ). It is not at all limiting as to the number of available functions and to the proposed functions. In that design, all converters are bidirectional as to the current, in order to especially allow for stocking the energy in the stocking module and for using the energy stocked in that module.

Of course, other designs could be foreseen, and it is well understood that the invention is not limited to the designs described above.

The invention also relates to the design of the system described above for using it in a functionalized infrastructure.

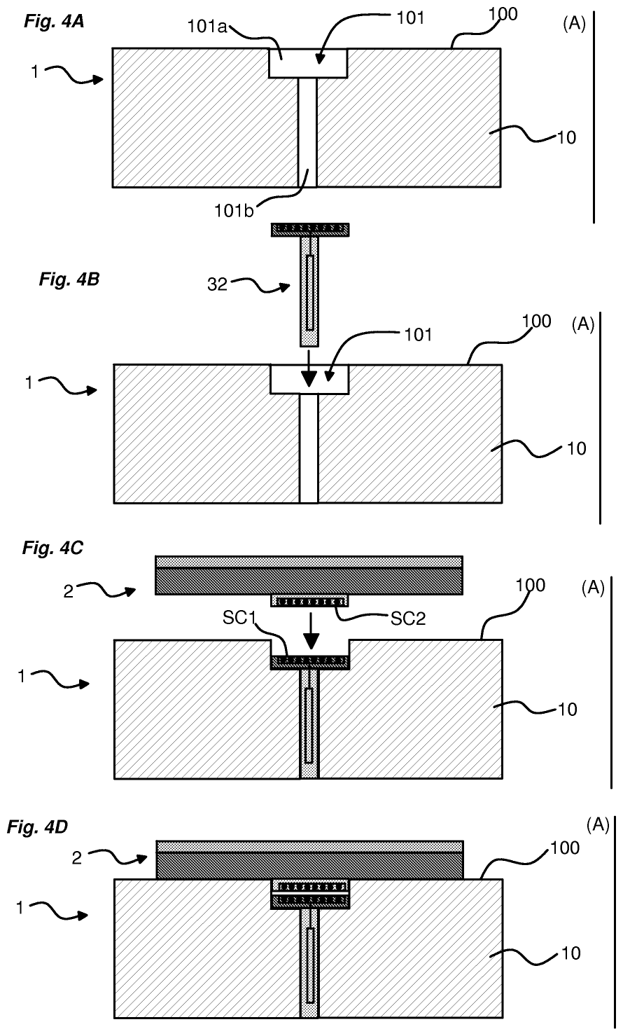

As already described above, an infrastructure such as a road comprises, for example, a lower layer 10 provided with a surface 100 to be covered. According to one aspect of the invention, that surface 100 to be covered is intended to be covered at least partially with the covering slabs 2 of the invention. Further, for lodging the first part 3 of the system, the solution is to produce n cavities 101 or holes in the lower layer 10 of the infrastructure, n being more than or equal to 1 (FIG. 4A). Each cavity is intended to receive a block 32 for contactless transmission of energy of the first part of the system, each block 32 being positioned in the cavity in a way to turn the coupling surface SC1 of its inductive coupler 320 upright (FIG. 4B).

Advantageously, each cavity 101 is always formed with standard dimensions, i.e. depth, opening dimensions, form of the opening.

Then, the opening of the cavity 101 is covered with a slab 2 (FIGS. 4C and 4D). Preferably, the mechanical means for positioning and centering are designed to allow a perfect positioning and centering of the slab 2 with respect to the cavity 101. What has to be done is, for example, to form the housing of the slab enclosing the inductive coupler, with adapted dimensions so that it cooperates, with a minimum tolerance, with the edge of the upper opening of the cavity.

The depth of each cavity is adapted in a way that the coupling surface SC1 of the block 32 be located at a sufficiently high level for favoring the transmission of energy between both couplers 220, 320.

In other words, in order to guarantee a satisfying coupling performance, it is necessary that both couplers 220, 320 be correctly situated facing each other as to x- and y-axes and be spaced apart from one another as to z-axis.

With reference to FIG. 4A, each cavity 101 is shaped, for example, such as to define an upper part 101a with a constant cross section which is extended by a lower part 101b that is narrower than the upper part and also has a constant cross section. The lower part of the cavity is intended to receive the second housing 34 of the block for contactless transmission of energy, and the upper part is intended to receive the first housing 33 of the block for contactless transmission of energy.

According to the invention, when the system comprises a first part with n blocks for transmission of energy and thus n inductive couplers, n being more than or equal to 2, the infrastructure is provided with n cavities of the type as described further up, so that each one receives a separate block 32 for contactless transmission of energy.

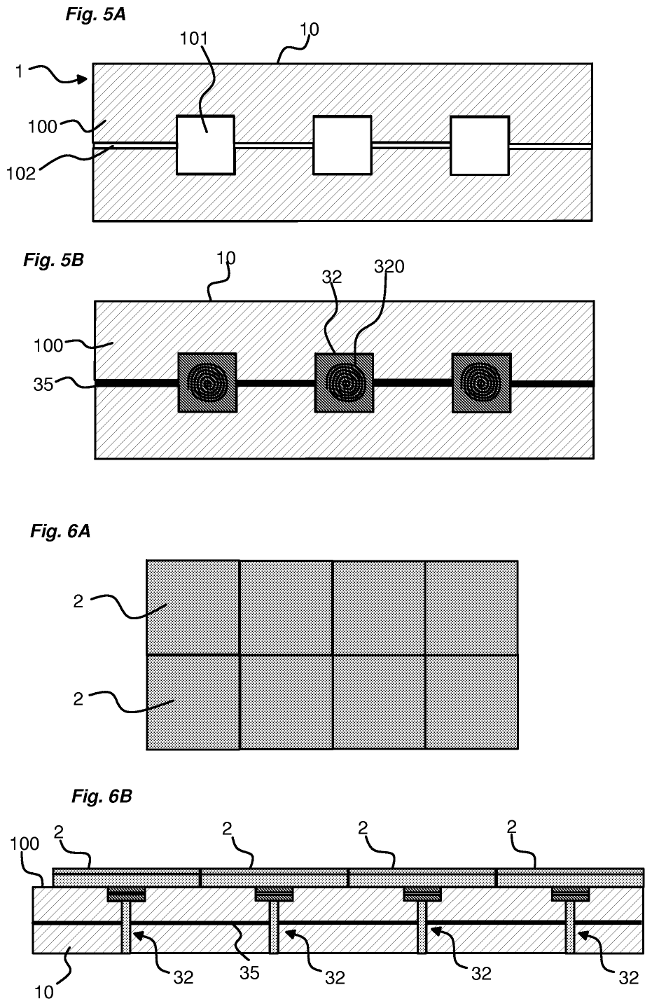

According to the invention, with reference to FIGS. 5A and 5B, the infrastructure comprises a trench 102 formed in the lower layer 10 and connecting each cavity 101 to an adjacent cavity.

According to the invention, in the system, each block 32 for contactless transmission of energy of the first part thus is connected to the adjacent block by at least one connection cable 35 forming some type of bus as of one of the electrical designs described above. And each connection cable 35 extends in a trench 102 connecting two cavities (FIG. 5B). The cable can have any adapted shape and will be connected from one block to the other. It could be, for example, a flexible net of wires.

As a result of the design of the system and of that of the infrastructure, it is easy to produce a functionalized infrastructure. The following steps have to be performed:
Making several cavities 101 and several trenches, a trench connecting a cavity to an adjacent cavity. Each cavity 101 has, for example, the shape described above of two separate volumes, one on top of the other, such as to form a narrowing.
Positioning the first part 3 of the system in such a way that each block 32 for contactless transmission of energy be positioned in a separate cavity. The coupling surface SC1 of the block is positioned to the top.
Positioning a covering slab on top of each cavity 101 in order to cover at least partially the surface 100 of the lower layer 10, the coupling surface SC2 of the slab being positioned in parallel to the surface SC1, and at a distance being determined by the mechanical positioning of the slab, that distance being adapted for allowing a contactless transmission of energy with the best possible performance.

Thus, FIG. 6A shows a surface which is entirely covered with slabs 2 according to the invention. As to FIG. 6B, it shows slabs positioned adjacently on the surface 100 of the lower layer 10. The outer surfaces of the n slabs that are positioned in a juxtaposed manner are arranged in a same plane forming the plane of the roadway. The n slabs put on the lower layer are adjusted with respect to one another, especially as far as dimensions are concerned, in order to form perfect junctions and thus pave the surface to be covered of the lower layer to a maximum.

Thus, the invention has a number of advantages, amongst which are:
An easy way of producing a functionalized infrastructure by simple positioning of functionalized slabs.
A possibility of configuring the infrastructure by mixing several types of slabs and, at the same time, maintaining a similar way of installation.
The possibility to hold low voltages away from the surface and to maintain a low voltage (TBTS) over the first centimeters of the thickness of the roadway.
An easy to maintain infrastructure, especially due to the possibility of easily replacing a defective slab without having to intervene on the whole infrastructure.

1. Covering slab (2) for an infrastructure, said infrastructure being functionalized by the addition of an electrical function, wherein the covering slab is formed by a monobloc assembly comprising:
an assembly (20) for the electrical functionalization of said slab, comprising a first layer, called an outer layer;
an electronics block (21) connected to said electrical functionalization assembly and comprising at least one bidirectional static converter (210);
a contactless energy transmission block (22) comprising an inductive coupler (220) provided with two terminals connected to the bidirectional static converter of said electronics block (21) and having a coupling surface located opposite said outer layer.

2. The covering slab according to claim 1, wherein the electrical functionalization assembly comprises a block for generating electrical energy.

3. The covering slab according to claim 2, wherein the electrical energy generator block comprises
photovoltaic cells (201) intended to convert luminous energy into an electrical energy.

4. The covering slab according to claim 1, wherein the electrical functionalization assembly comprises a block for receiving electrical energy.

5. The covering slab according to claim 4, wherein the electrical energy receiving block comprises an electronics circuit for luminous and/or sound signaling.

6. The covering slab according to claim 4, wherein the electrical energy receiving block comprises a device for charging an electrical appliance by induction.

7. The covering slab according to claim 4, wherein the electrical energy receiving block comprises a device for counting vehicles.

8. The covering slab according to claim 4, wherein the electrical energy receiving block comprises one or more terminals for connection to one or more wireless communication networks.

9. The covering slab according to claim 4, wherein the electrical energy receiving block comprises a heating structure.

10. System for contactless transmission of electrical energy for an infrastructure, said infrastructure being functionalized by the addition of a function, the system comprising:
a first part (3) comprising n blocks (32) for contactless transmission of energy, each block comprising an inductive coupler, with n being more than or equal to 1, each inductive coupler (320) comprising a coupling surface (SC1);
a second part comprising n covering slab(s) (2), each covering slab being as defined in claim 1.

11. The system according to claim 10, wherein:
the first part (3) comprises n blocks for contactless transmission of energy, n being more than or equal to 2;
each inductive coupler (320) of the first part is electrically connected to an adjacent inductive coupler by means of a connection cable (35).

12. The system according to claim 10, wherein the first part comprises n static converter(s) (310), each one being associated to a separate inductive coupler (320) of the first part.

13. The system according to claim 12, wherein, in the first part, the n static converter(s) are of the AC/DC type, and wherein the system comprises a central converter (4) of the DC/AC type, and wherein the n static converter(s) of the AC/DC type are connected in parallel to the central converter.

14. The system according to claim 13, further comprising a module (5) for stocking electrical energy which is connected in parallel to the n converter(s) connected to the central converter.

15. The system according to claim 12, wherein, in the first part, the n static converter(s) (310) are of the AC/AC type.

16. The system according to claim 12, further comprising a central converter (4) of the AC/AC type, and wherein the n inductive coupler(s) of the first part are connected in parallel to the central AC/AC converter.

17. The system according to claim 12, wherein, in the first part, the n static converter(s) are of the DC/AC type, and wherein the system comprises a central converter (4) of the AC/AC type, and wherein the n static converter(s) of the DC/AC type are connected in parallel to the central converter.

18. Infrastructure, said infrastructure being functionalized by the addition of a function of the electrical energy generator type and/or the electrical energy receiver type, and comprising a system for contactless transmission of electrical energy, said infrastructure comprising a lower layer (10) which comprises a surface (100) to be covered and in which n cavities (101) are formed, n being more than or equal to 1, wherein said infrastructure comprises:
a first part (3) comprising an inductive coupler (320) located in each cavity (101) in a way to have a first coupling surface (SC1);
a second part comprising n covering slab(s) (2) such as defined in claim 1, each covering slab (2) being positioned on said surface (100) to be covered in order to cover a separate cavity (101) and to turn an outer face of the covering slab to the outside of said cavity and coupling surface (SC2) of the covering slab to the inside of said cavity facing the coupling surface (SC1) of the inductive coupler located inside the cavity.

19. The functionalized infrastructure according to claim 18, wherein:
said surface (100) to be covered of the lower layer (10) comprises n cavities, n being more than or equal to 2;
said infrastructure comprises a trench (102) linking each cavity (101) to an adjacent cavity;
the first part of the system comprises several inductive couplers (320), each being located in a separate cavity (101);
from one cavity to an adjacent cavity, the inductive couplers (320) are linked to one another by a connection cable (35) extending in said trench (102).

20. The functionalized infrastructure according to claim 18, wherein said n covering slabs are juxtaposed in such a way that their outer surface of their outer layer is located in a same plane.

21. Method of installing a functionalized infrastructure as defined in claim 18, the method comprising the steps of:
forming n cavities (101) in the lower layer, n being more than or equal to 2;
positioning the first part such as to occupy each cavity with a separate inductive coupler (320);
positioning a separate covering slab (2) on a separate cavity (101) such as to turn an outer face of the separate covering slab to the outside of the cavity and a coupling surface (SC2) of the separate covering slab to the inside of said cavity opposite the coupling surface (SC1) of the inductive coupler located inside the cavity.
